(19) United States
(12) Patent Application Publication
(10) Pub. No.: US 2012/0270408 A1
(43) Pub. Date: Oct. 25, 2012

(54) MANUFACTURING METHOD OF GATE DIELECTRIC LAYER

(75) Inventors: Kuo-Hui Su, Taipei City (TW); Yi-Nan Chen, Taipei City (TW); Hsien-Wen Liu, Taoyuan County (TW)

(73) Assignee: NANYA TECHNOLOGY CORPORATION, Taoyuan (TW)

(21) Appl. No.: 13/093,838

(22) Filed: Apr. 25, 2011

(51) Int. Cl. H01L 21/31

(52) U.S. Cl. 438/762; 257/E21.24

(57) ABSTRACT

A manufacturing method of a gate dielectric layer that includes a nitride layer and an oxide layer is provided. A substrate is provided. A nitridation treatment is performed to form the nitride layer on the substrate. An oxidation treatment is performed subsequent to the formation of the nitride layer to form the oxide layer between the nitride layer and the substrate.

### BACKGROUND

1. Field of the Invention

The present invention relates to a manufacturing method of a dielectric layer, more particularly to a manufacturing method of a gate dielectric layer.

2. Description of Related Art

As the dimension of a metal-oxide-semiconductor (MOS) transistor gradually reduces, the demand on the quality of the gate dielectric layer in a MOS transistor, and more particularly the dielectric characteristic between the substrate and the gate dielectric layer, correspondingly increases.

During the current manufacturing process of a gate dielectric layer, an oxidation treatment is first performed on the substrate to form an oxide layer on the substrate. Then, a nitridation treatment is performed to form a nitride layer on the oxide layer. Thereafter, an annealing treatment is performed to stabilize the properties of the already formed film layers. The above-mentioned oxide layer and nitride layer constitute a gate dielectric layer.

However, after the above annealing treatment, the nitrogen atom (N) in the nitride layer tends to penetrate through the underlying oxide layer to generate defects at the interface between the oxide layer and the substrate; hence, the efficiency and the throughput of the device are thereby lowered.

### SUMMARY OF THE DISCLOSURE

An exemplary embodiment of the invention provides a manufacturing method of a gate dielectric layer having a higher quality.

An exemplary embodiment of the invention provides a manufacturing method of a gate dielectric layer, and the gate dielectric layer includes a nitride layer and an oxide layer. The manufacturing method of a gate dielectric layer includes providing a substrate. A nitridation treatment is then performed to form a nitride layer on the substrate. Thereafter, an oxidation treatment is performed to form an oxide layer between the nitride layer and the substrate.

According to an exemplary embodiment of the invention in forming a gate dielectric layer, the nitrogen content in the above gate dielectric layer is greater than 25%.

According to an exemplary embodiment of the invention in forming a gate dielectric layer, the above nitridation treatment includes performing a decoupled plasma nitridation (DPN) process.

According to an exemplary embodiment of the invention in forming a gate dielectric layer, the above oxidation treatment includes performing an in-situ steam generation (ISSG) process.

According to an exemplary embodiment of the invention in forming a gate dielectric layer, the thickness of the above-mentioned nitride layer is less than 10 angstrom.

According to an exemplary embodiment of the invention in forming a gate dielectric layer, the thickness of the above-mentioned oxide layer is less than 25 angstrom.

Accordingly, during the fabrication of a gate dielectric layer of an exemplary embodiment of the invention, a nitridation treatment is performed prior to an oxidation treatment. The penetration of nitrogen through the already-formed oxide layer during the nitridation treatment and the generation of defects at the interface between the nitride layer and the substrate can be circumvented. Moreover, since the oxidation treatment is considered as a high temperature treatment process, an additional annealing process for stabilizing the properties of the already-formed film layers can be omitted.

The invention and certain merits provided by the invention can be better understood by way of the following exemplary embodiments and the accompanying drawings, which are not to be construed as limiting the scope of the invention.

### BRIEF DESCRIPTION OF THE DRAWINGS

FIGS. 1A and 1B show the steps for fabricating a gate dielectric layer according to an exemplary embodiment of this invention in a cross-sectional view.

### DESCRIPTION OF EMBODIMENTS

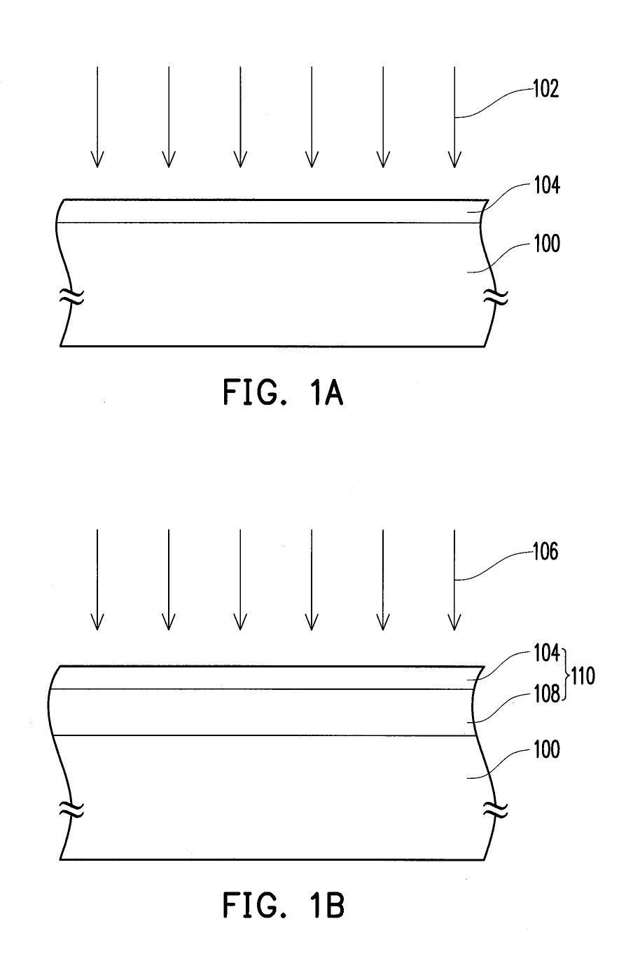

FIGS. 1A and 1B show the steps for fabricating a gate dielectric layer according to an exemplary embodiment of this invention in a cross-sectional view. The gate dielectric is constructed with an oxide layer and a nitride layer. Referring to FIG. 1A, a substrate 100 is provided. The substrate 100 is, for example, a silicon substrate. Then, a nitridation treatment 102 is performed on the substrate 100 to form a nitride layer 104 on the substrate 100. The nitridation treatment 102 is accomplished by, for example, performing a decoupled plasma nitridation (DPN) process. The thickness of the nitride layer 104 is less than 10 angstrom.

An oxidation treatment 106 is subsequently performed on the substrate 100 to form an oxide layer 108 between the nitride layer 104 and the substrate 100. The oxidation treatment 106 includes performing an in situ steam generation process. The thickness of the oxide layer 108 is less than 25 angstrom. The nitride layer 104 and the oxide layer 108 form a gate dielectric layer 110.

Since the gate dielectric layer 110 is constructed with a nitride layer 104 and an oxide layer 108, the gate dielectric layer 110 of the exemplary embodiment comprises a higher dielectric constant, while the thickness thereof is smaller than a typical gate oxide layer. Moreover, under a same thickness of a gate dielectric layer, the gate dielectric layer 110 constructed with the nitride layer 104 and the oxide layer 108 has a higher dielectric constant.

In the exemplary embodiment, the oxidation treatment 106 is performed after the nitride layer 104 is formed, such that oxygen penetrates the nitride layer 104 and the oxide layer 108 is formed between the substrate 100 and the nitride layer 104. Therefore, the penetration of nitrogen through the already-formed oxide layer and the generation of defects at the interface between the nitride layer and the substrate can be obviated.

More particularly, the manufacturing method of the gate dielectric layer of the exemplary embodiment is suitable for forming a gate dielectric layer with the nitrogen content higher than 25%. More specifically, to obviate the nitrogen from penetrating through the already-formed oxide layer during the nitridation treatment and generating defects at the interface between the oxide layer and the substrate, it is conventionally to use a small amount of nitrogen during the nitridation treatment. In other words, the nitrogen content in the gate dielectric layer formed according to the conventional approach is very low. However, even with the conventional approach, the above-mentioned problem of the nitrogen-penetration through the oxide layer can not be effectively avoided. According to the exemplary embodiment of the invention, since the nitridation treatment is performed prior to the oxidation treatment, a large amount of nitrogen (which implies the gate dielectric layer that is being formed will contain a high concentration of nitrogen) may be applied during the nitridation treatment process, while the problems usually encountered in the conventional approach are prevented. In one exemplary embodiment, the nitrogen content in the gate dielectric layer 110 may be higher than 25%.

Accordingly, during the fabrication of the gate dielectric layer of the exemplary embodiment of the invention, a nitridation treatment is first performed to form a nitride layer, followed by performing an oxidation treatment to form an oxide layer. Hence, the penetration of nitrogen through the already-formed oxide layer during the nitridation treatment and the generation of defects at the interface between the nitride layer and the substrate can be obviated.

Moreover, the oxidation treatment is considered as a high temperature treatment process. Hence, during the formation of the gate dielectric layer of the exemplary embodiment of the invention, an additional annealing process for stabilizing the properties of the already-formed film layers can be omitted. Accordingly, a simplified process is thereby achieved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A manufacturing method of a gate dielectric layer comprising a nitride layer and an oxide layer, the manufacturing method comprising:
providing a substrate;
performing a nitridation treatment to form a nitride layer on the substrate; and
performing an oxide treatment subsequent to the formation of the nitride layer to form an oxide layer only between the nitride layer and the substrate.

2. The manufacturing method of claim 1, wherein the nitride layer is formed with a nitrogen content greater than 25%.

3. The manufacturing method of claim 1, wherein the nitridation treatment is conducted by performing a decoupled plasma nitridation process.

4. The manufacturing method of claim 1, wherein the oxidation treatment is conducted by performing an in situ steam generation process.

5. The manufacturing method of claim 1, wherein the nitride layer is formed with a thickness less than 10 angstrom.

6. The manufacturing method of claim 1, wherein the oxide layer is formed with a thickness less than 25 angstrom.
